(19) United States
(12) Patent Application Publication
(10) Pub. No.: US 2013/0270980 A1
(43) Pub. Date: Oct. 17, 2013

(54) PROTECTIVE SHEATH

(71) Applicant: Fu-Yi HSU, New Taipei City (TW)

(72) Inventor: Fu-Yi HSU, New Taipei City (TW)

(21) Appl. No.: 13/685,773

(22) Filed: Nov. 27, 2012

(30) Foreign Application Priority Data
Apr. 11, 2012 (TW) 101206547

(51) Int. Cl. H05K 5/03

(52) U.S. Cl. CPC H05K 5/03
USPC 312/223.1

(57) ABSTRACT

A protective sheath comprises a first holding component for holding a portable electronic device, a second holding component for holding an input device, and a support component. The support component has a first foldable plate and a second foldable plate adjacent to and capable of being folded relative to each other. The first foldable plate is pivoted to the first holding component. The second foldable plate is glidingly disposed to the second holding component. The first holding component can be not only unfolded relative to the second holding component and the first foldable plate for enabling the portable electronic device to stand on a second inner surface of the second holding component, but also folded relative to the second holding component and the first foldable plate for covering a display surface of the portable electronic device together with the input device and the second inner surface.

### CROSS-REFERENCE TO RELATED APPLICATIONS

This application claims priority from Taiwan Patent Application No. 101206547, filed 2012 Apr. 11, the contents of which are hereby incorporated by reference in their entirety for all purposes.

### FIELD OF THE INVENTION

The present invention generally relates to a protective sheath, and more particularly to a protective sheath suitable for a portable electronic device and an input device.

### DESCRIPTION OF THE RELATED ART

With the development of technology, various portable electronic devices, such as a multimedia player (MP3, MP4 and so on), a cell phone, a personal digital assistant (PDA), a hand-held game console, an electronic book (E-book), a tablet personal computer (tablet PC), a netbook, a notebook and so on, have become an integral part of modern life to many people. To compare with the traditional desktop PC, a main advantage of the portable electronic device is easy to get carried. As a result, in recent years, we can see people operating the portable electronic devices anytime and anywhere.

It should be noted that only some portable electronic devices, such as the netbook, the notebook and some kinds of the hand-held game consoles mentioned above, are generally designed into two bodies respectively disposed with a keyboard and a screen and capable of being folded relative to each other. In such portable electronic devices, the body disposed with the screen can stand up with a support provided by the body disposed with the keyboard, and an inclination of the screen relative to the keyboard is adjustable as well, so as to enable the portable electronic devices to be held or put on a carrying surface (such as a table surface) to be watched or operated based upon an operation requirement of a user. In contrast, the other portable electronic devices are generally formed as an integral design and necessary to be assisted in standing on the carrying surface with an additional cradle or another supporting component.

However, the cradle is not always carried with the portable electronic devices by the user, and a proper supporting component is not readily available. Thus, some manufacturers designed some kinds of protective sheaths capable of receiving both of the portable electronic device and the keyboard, so as to enable the portable electronic device to stand with a support provided by the protective sheath and the keyboard. It should be noted that all kinds of the commercially available protective sheaths can support a portable electronic device to stand on a carrying surface merely in a specific angle, i.e. a tilt angle of the portable electronic device standing on the carrying surface is unable to be adjusted based upon an operation requirement of the user by the protective sheaths.

### SUMMARY OF THE INVENTION

The present invention is directed to a protective sheath capable of enabling a tilt angle of the portable electronic device standing on the second inner surface of the second holding component to be adjusted based upon an operation requirement of the user.

The present invention provides a protective sheath for a portable electronic device and an input device, which comprises a first holding component, a second holding component and a support component. The first holding component is capable of holding the portable electronic device on a first inner surface of the first holding component from a first rear surface of the portable electronic device, while the second holding component is capable of holding the input device on a second inner surface of the second holding component from a second rear surface of the input device. The support component has a first foldable plate and a second foldable plate adjacent to each other and capable of being folded relative to each other. Herein, a first side edge of the first foldable plate away from the second foldable plate is pivoted to the first holding component, and a second side edge of the second foldable plate away from the first foldable plate is glidingly disposed to the second holding component. In addition, the first holding component is capable of being unfolded relative to the second holding component and the first foldable plate, so as to enable the portable electronic device to stand on the second inner surface with a support provided by the input device and the first foldable plate, and the first holding component is capable of being folded relative to the second holding component and the first foldable plate, so as to enable the input device and the second inner surface to cover a display surface of the portable electronic device together.

According to an embodiment of the present invention, the first holding component comprises a rear plate and a first holding portion, and the rear plate has the first inner surface. Herein, the first holding portion comprises a silicon case, a leather case, a plastic case, at least an elastic, at least a fastening strap (for example a Velcro® strap) or at least an adhesive unit disposed on the first inner surface, or at least a hook disposed on a part of a peripheral of the rear plate, or a combination thereof.

According to an embodiment of the present invention, the first holding component is a silicon case, a leather case or a plastic case.

According to an embodiment of the present invention, the first holding component further has a third side edge adjacent to the second holding component, a fourth side edge opposite to the third side edge, a fifth side edge connecting with the third side edge and the fourth side edge, a sixth side edge opposite to the fifth side edge and a center region located among the third side edge, the fourth side edge, the fifth side edge and the sixth side edge, and the first foldable plate is pivoted to at least part of the third side edge, at least part of the fourth side edge or the center region, or extends from the fifth side edge to the sixth side edge.

According to an embodiment of the present invention, the second holding component comprises a cover plate and a second holding portion, and the cover plate has the second inner surface. Herein, the second holding portion comprises at least an elastic, at least a fastening strap (for example a Velcro® strap), at least an insertion portion or at least an adhesive unit disposed on the second inner surface, or at least a hook disposed on a part of a peripheral of the cover plate, or a combination thereof.

According to an embodiment of the present invention, the support component further comprises a third holding portion, and the third holding portion comprises at least an elastic or at least a fastening strap (for example a Velcro® strap) disposed on a third inner surface of the first foldable plate, or a plurality of hooks disposed on a part of a peripheral of the first foldable plate, or a combination thereof.

According to an embodiment of the present invention, the second holding component further has an opening and a receiving space connecting with the opening, wherein the second foldable plate is glidingly disposed to the opening, and the second side edge is glidingly disposed within the receiving space. In a preferred embodiment, the support component can further have a position limiting portion disposed to the second side edge. In addition, a first length of the second foldable plate can be shorter than a second length of the opening, while a third length of the position limiting portion can be longer than the second length and shorter than a fourth length of the receiving space. Furthermore, a fifth length of the position limiting portion can be shorter than a sixth length of the receiving space. Besides, all of the first length, the second length, the third length and the fourth length can be substantially parallel to the second side edge, while both of the fifth length and the sixth length can be substantially perpendicular to the second side edge. In another preferred embodiment, the opening can be formed at a seventh side edge of the second holding component adjacent to the first holding component.

According to an embodiment of the present invention, at least one of the second holding component and the second foldable plate further has at least a slide rail, and the second foldable plate is glidingly disposed to the second holding component via the slide rail. In a preferred embodiment, the slide rail can further have at least a position limiting portion capable of limiting a relative position between the second holding component and the second foldable plate.

According to an embodiment of the present invention, the first foldable plate is made of solid leather, while the second foldable plate is made of solid leather or soft leather.

According to an embodiment of the present invention, the protective sheath further comprises a hinge, wherein the first side edge is pivoted to a first outer surface of the first holding component opposite to the first inner surface via the hinge. In a preferred embodiment, the hinge can be an embedded hinge or an exposed hinge.

According to an embodiment of the present invention, the protective sheath further comprises a third holding component, wherein the third holding component is disposed to at least one of the first holding component and the second holding component, and capable of maintaining the first holding component and the second holding component being folded relative to each other. In a preferred embodiment, the third holding component can be at least an elastic disposed to at least one of the first holding component and the second holding component. In another preferred embodiment, the third holding component can be a zipper set, at least a fastening strap (for example a Velcro® strap), at least a snap button set, at least a pair of permanent magnets with opposite magnet polarities, a combination of at least a permanent magnet and at least a ferromagnetic material artifact, a combination of at least a hook and at least a locking aperture, a combination of at least a pin and at least an inserting aperture, or a combination listed above, and can be disposed to both of the first holding component and the second holding component. In a further preferred embodiment, the first holding component can further have a third foldable plate, wherein the third foldable plate is capable of being folded toward a second outer surface of the second holding component opposite to the second inner surface when the first holding component and the second holding component are folded relative to each other, and the third holding component can be disposed to both of the third foldable plate and the second outer surface. In another further preferred embodiment, the second holding component can further have a fourth foldable plate, wherein the fourth foldable plate is capable of being folded toward a first outer surface of the first holding component opposite to the first inner surface when the first holding component and the second holding component are folded relative to each other, and the third holding component can be disposed to both of the fourth foldable plate and the first outer surface.

According to an embodiment of the present invention, the portable electronic device is a multimedia player, a cell phone, a PDA, a hand-held game console, a tablet PC or an E-book.

According to an embodiment of the present invention, the input device is a keyboard or a graphics tablet.

Accordingly, not only the relative position but also the relative angle between the first holding component and the second holding component are adjustable since the first foldable plate of the support component is pivoted to the first holding component and the second foldable plate of the support component is glidingly disposed to second holding component. As a result, the protective sheath provided in the present invention can be utilized to not only protect the portable electronic device, but also support the portable electronic device to stably stand on a carrying surface anytime and anywhere. Besides, a tilt angle of the portable electronic device standing on the carrying surface is adjustable based upon an operation requirement with the protective sheath as well.

### BRIEF DESCRIPTION OF THE DRAWINGS

FIG. 1 illustrates a structural schematic top view of a protective sheath disassembled from a portable electronic device and an input device according to a preferred embodiment of the present invention.

FIG. 2 illustrates a top view of a first usage of the protective sheath as illustrated in FIG. 1, wherein both of the portable electronic device and the input device are assembled thereon.

FIG. 3 illustrates a side view of the protective sheath as illustrated in FIG. 2 assisting the portable electronic device to stand up.

FIG. 4 illustrates a top view of a second usage of the protective sheath as illustrated in FIG. 2, wherein both of the portable electronic device and the input device are assembled thereon.

FIG. 5 illustrates a side view of the protective sheath as illustrated in FIG. 4 assisting the portable electronic device to stand up.

### DETAILED DESCRIPTION OF THE INVENTION

Reference will now be made in detail to specific embodiments of the present invention. Examples of these embodiments are illustrated in the accompanying drawings. While the invention will be described in conjunction with these specific embodiments, it will be understood that it is not intended to limit the invention to these embodiments. In fact, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations are not described in detail in order not to obscure the present invention.

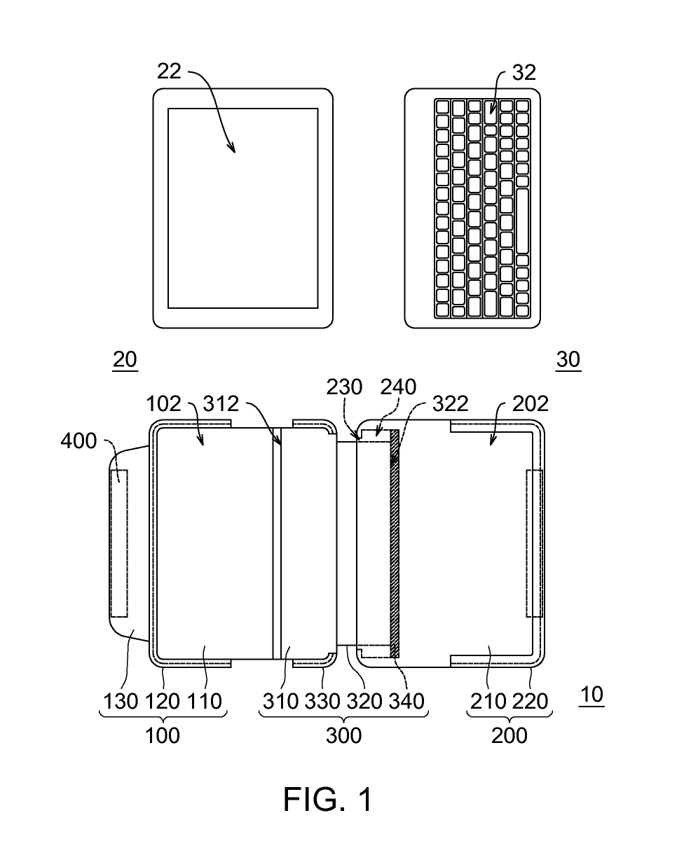

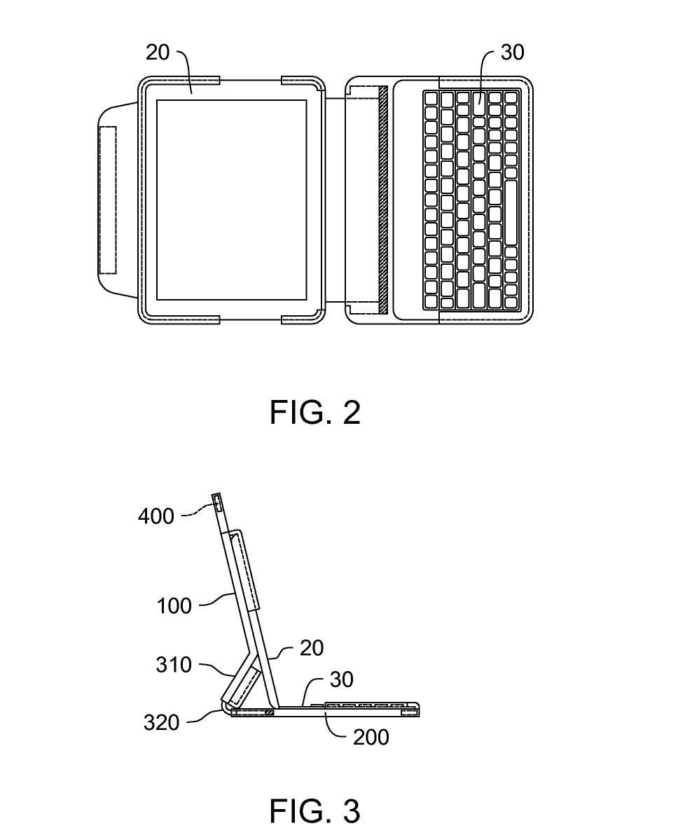

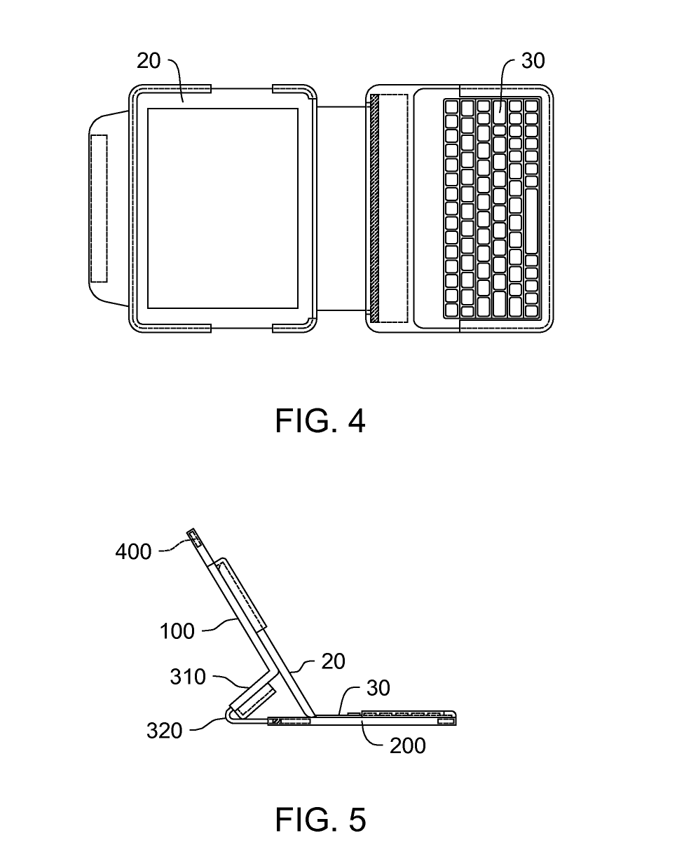

FIG. 1 illustrates a structural schematic top view of a protective sheath disassembled from a portable electronic device and an input device according to a preferred embodiment of the present invention. Further, FIG. 2 illustrates a top view of a first usage of the protective sheath as illustrated in FIG. 1, wherein both of the portable electronic device and the input device are assembled thereon, while FIG. 3 illustrates a side view of the protective sheath as illustrated in FIG. 2 assisting the portable electronic device to stand up. In addition, FIG. 4 illustrates a top view of a second usage of the protective sheath as illustrated in FIG. 2, wherein both of the portable electronic device and the input device are assembled thereon, while FIG. 5 illustrates a side view of the protective sheath as illustrated in FIG. 4 assisting the portable electronic device to stand up. In the following embodiment, the same or similar components refer to the same symbols. Besides, all of the upper side, the lower side, the left side and the right side described in the following embodiments refer to the orientation of FIG. 1.

Referring to FIG. 1 first, the protective sheath 10 of the present invention can be assembled on a portable electronic device 20 and an input device 30, wherein the portable electronic device 20 can have a display surface 22, while the input device 30 can have an operation surface 32. In the present preferred embodiment, the portable electronic device 20 is exemplarily illustrated as a tablet PC, while the input device 30 is exemplarily illustrated as a keyboard. However, in other non-illustrated embodiments, the portable electronic device can further be a multimedia player (MP3, MP4 and so on), a cell phone, a PDA, a hand-held game console, a E-book or any other kind of tablet portable electronic devices, and the input device can further be a graphics tablet or any other kind of tablet input devices.

Hereinafter, referring to FIG. 1, FIG. 2 and FIG. 3 together, the protective sheath 10 comprises a first holding component 100, a second holding component 200 and a support component 300. Herein, the first holding component 100 is capable of holding the portable electronic device 20 on a first inner surface 102 of the first holding component 100 from a rear surface of the portable electronic device 20. In the present preferred embodiment, the first holding component 100 can comprise a rear plate 110 and a first holding portion 120. Herein, the rear plate 110 is capable of covering a part of the rear surface of the portable electronic device 20, and the first holding portion 120 can be a hook extending from a lower side edge through a left side edge to an upper side edge of the rear plate 110.

In addition, the second holding component 200 is capable of holding the input device 30 on a second inner surface 202 of the second holding component 200 from a rear surface of the input device 30. In the present preferred embodiment, the second holding component 200 can comprises a cover plate 210 and a second holding portion 220. Herein, the cover plate 210 is capable of covering the display surface 22 together with the input device 30 when the first holding component 100 and the second holding component 200 are folded relative to each other, while the second holding portion 220 can be another hook extending from a lower side edge through a right side edge to an upper side edge of the cover plate 210.

Furthermore, the support component 300 has a first foldable plate 310 and a second foldable plate 320 adjacent to each other and capable of being folded relative to each other, and can further have a third holding portion 330. Herein, a left side edge 312 of the first foldable plate 310 is pivoted to a right side edge of the rear plate 110, while a right side edge 322 of the second foldable plate 320 is glidingly disposed to the second holding component 200. It should be noted that the first foldable plate 310 should be made of a solid material, for example solid leather, since it is used for supporting the portable electronic device 20 (as illustrated in FIG. 3). In the present preferred embodiment, the structure of the first foldable plate 310 and the rear plate 110 pivoting to each other is made of, for example but not limited to, aligning two solid plates (such as plastic plates, solid leather plates and so on) with each other end to end and jointing the two solid plates together as an integral part by attaching soft leather over the two adjacent ends, so as to connect the two solid plates together and to enable the two solid plates to be folded relative to each other via the soft leather.

In contrast, the second foldable plate 320 can be made of a soft material, for example soft leather, since it is used for movably connecting the first foldable plate 310 to the second holding component 200, so as to enable the first foldable plate 310 and the second holding component 200 to be rotated relative to each other by folding the second foldable plate 320. However, the second foldable plate 320 can be made of a solid material, for example solid leather as well. In such a case, the first foldable plate 310 and the second foldable plate 320 must be connected to each other by additionally using a hinge or any other kind of foldable mechanism. In addition, the third holding portion 330 in the present preferred embodiment is composed of two hooks respectively extending from the lower side edge to the lower right corner and from the upper side edge to the upper right corner of first foldable plate 310, so as to hold the portable electronic device 20 together with the first holding portion 120 when the first holding component 100 and the first foldable plate 310 are unfolded relative to each other. However, in other non-illustrated embodiments, the third holding portion can further be at least an elastic, at least a fastening strap (for example a Velcro® strap) or a combination thereof disposed on a third inner surface of the first foldable plate.

Based upon the structures described above in detail, the portable electronic device 20 can disengage from the third holding portion 330 by folding the first holding component 100 and the first foldable plate 310 relative to each other first. Thereafter, the right side edge of the portable electronic device 20 can further lean against the left side edge of the input device 30 by folding the first foldable plate 310 and the second foldable plate 320 relative to each other. As a result, as illustrated in FIG. 3, the portable electronic device 20 can stand on the second inner surface 202 with a support provided by the input device 30 and the first foldable plate 310. In addition, not only the relative position between the first holding component 100 and the second holding component 200 but also the tilt angle of the portable electronic device 20 standing on the second inner surface 202 can be adjusted based upon the operation requirement when the portable electronic device 20 stands on the second inner surface 202 since the right side edge of the second foldable plate 320 is glidingly disposed to the second holding component 200.

In detail, in the present preferred embodiment, the second holding component 200 can further have an opening 230 formed at a left side edge of the cover plate 210 and a receiving space 240 connecting with the opening 230, and the support component 300 can further have a position limiting portion 340 disposed at the right side edge 322. Herein, along a vertical direction, a length of the right side edge of the second foldable plate 320 can be slightly shorter than a length of the opening 230, while a length of the position limiting portion 340 can be longer than the length of the opening 230, and can be slightly shorter than a length of the receiving space 240. In addition, along a horizontal direction, a length of the position limiting portion 340 should be shorter than a length of the receiving space 240. Hence, not only the second foldable plate 320 can slide relative to the opening 230, but also the position limiting portion 340 can slide within the receiving space 240 between a location as illustrated in FIG. 2 and a location as illustrated in FIG. 4, so as to enable the relative position between the first holding component 100 and the second holding component 200 to be adjusted. As a result, the tilt angle of the portable electronic device 20 can be adjusted between a location as illustrated in FIG. 3 and a location as illustrated in FIG. 5. Besides, the position limiting portion 340 is not likely to disengage from the receiving space 240 when the position limiting portion 340 is sliding within the receiving space 240.

In an instance, the cover plate 210 can be formed by, for example but not limited to, adhering two pieces of leather together first and then sewing edges thereof together. In such an instance, the receiving space 240 can be formed between the two pieces of leather by not adhering whole of the two pieces of leather together (i.e. only adhering parts of peripherals and parts of internals of the two pieces of leather together), even by further forming a dent between the two pieces of leather. In addition, the opening 230 can be formed between the two pieces of leather by not sewing whole of the left side edges of the two pieces of leather together (i.e. only sewing two opposite ends of the left side edges together). Moreover, the position limiting portion 340 can be formed by a rod made of a solid material and fixed at the right side edge 322 of the second foldable plate 320.

Besides, as illustrated in FIG. 1, in the present preferred embodiment, the first holding component 100 can further have a third foldable plate 130, and the protective sheath 10 can further have a third holding component 400. Further, in the present preferred embodiment, the third foldable plate 130, for example but not limited to, extends outward from the left side edge of the rear plate 110, and the third holding component 400 is composed of, for example but not limited to, a pair of permanent magnets with opposite magnet polarities, wherein the pair of permanent magnets are respectively disposed within the third foldable plate 130 and the cover plate 210. In such a case, the third foldable plate 130 can be further folded toward the rear surface of the second holding component 200 when the first holding component 100 and second holding component 200 are folded relative to each other for covering the portable electronic device 20 and the input device 30 together. Subsequently, the pair of permanent magnets (i.e. the third holding component 400) can maintain the first holding component 100 and the second holding component 200 being folded relative to each other by attracting the pair of permanent magnets together with magnetic force. However, in other non-illustrated embodiments, the second holding component can have a fourth foldable plate instead, and the pair of permanent magnets (i.e. the third holding component) can be respectively disposed within the fourth foldable plate and the rear plate instead, wherein all of the arrangements, the structures and the functions of the fourth foldable plate are substantially the same as the third foldable plate and thus omitted herein.

However, it should be understood by those of skill in the art that the present invention can be practiced by more embodiments. For example, in other non-illustrated embodiments, the first holding portion can be a silicon case, a leather case or a plastic case disposed on the rear plate for substantially covering all of the side edges and the rear surface of the portable electronic device, at least an elastic or at least a fastening strap (for example a Velcro® strap) for tying on the portable electronic device, at least an adhesive unit for adhering the portable electronic device or a combination thereof. Alternatively, the first holding component can be a silicon case, a leather case or a plastic case without the additional rear plate as illustrated in the foregoing embodiments for directly covering all of the side edges and the rear surface of the portable electronic device as well. In such a case, a left side edge of the first foldable plate can be pivoted to not only a right side edge but also a left side edge or a center region of the rear surface of the first holding component as well. Moreover, the left side edge of the first foldable plate can further extend from the upper side edge of the first holding component to the lower side edge of the first holding component. Furthermore, the first foldable plate can be pivoted to the first holding component not only by the structures as illustrated above, but also by an embedded hinge or an exposed hinge.

Moreover, in other non-illustrated embodiments, the second holding portion can be at least an elastic, at least a fastening strap (for example a Velcro® strap), at least an insertion portion or at least an adhesive unit disposed on the cover plate, or a combination thereof as well. Alternatively, the second holding portion can also be any kind of structures capable of holding the input device on the cover plate. Besides, the second foldable plate should not be limited to the structures for being glidingly disposed to the second holding component as illustrated above. In other non-illustrated embodiments, at least one of the second holding component and the second foldable plate can further have at least a slide rail, so that the second foldable plate can be glidingly disposed to the second holding component via the slide rail. Furthermore, the slide rail can further have at least a position limiting portion, so as to limit the relative position between the second holding component and the second foldable plate. As a result, the relative position between the first holding component and the second holding component can further be effectively adjusted based upon the operation requirement.

Besides, the third holding component should not be limited to a pair of permanent magnets with opposite magnet polarities. In other non-illustrated embodiments, the third holding component can also be at least an elastic disposed to at least one of the first holding component and the second holding component for tying the first holding component together with the second holding component as they are folded relative to each other. Alternatively, the third holding component can further be a zipper set, at least a fastening strap (for example a Velcro® strap), at least a snap button set, a combination of at least a permanent magnet and at least a ferromagnetic material artifact, a combination of at least a hook and at least a locking aperture, a combination of at least a pin and at least an inserting aperture, or a combination listed above, and is disposed to both of the first holding component and the second holding component.

In summary, in the present invention, because the portable electronic device and the input device can be respectively held on the first holding component and the second holding component of the protective sheath, the protective sheath provided in the present invention can not only protect the portable electronic, but also be conveniently carried together with the portable electronic device and the input device. In addition, because the first foldable plate of the support component is pivoted to the first holding component, and the second foldable plate of the support component is glidingly disposed to the second holding component, not only the relative position but also the relative angle between the first holding component and the second holding component are adjustable. As a result, not only the protective sheath can be used for supporting the portable electronic device to stably stand on a carrying surface anytime and anywhere, but also a tilt angle of the portable electronic device can be adjusted based upon the operation requirement.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A protective sheath for a portable electronic device and an input device, wherein the portable sheath comprises:
a first holding component, capable of holding the portable electronic device on a first inner surface of the first holding component from a first rear surface of the portable electronic device;
a second holding component, capable of holding the input device on a second inner surface of the second holding component from a second rear surface of the input device; and
a support component, having a first foldable plate and a second foldable plate adjacent to each other and capable of being folded relative to each other, wherein a first side edge of the first foldable plate away from the second foldable plate is pivoted to the first holding component, a second side edge of the second foldable plate away from the first foldable plate is glidingly disposed to the second holding component, the first holding component is capable of being unfolded relative to the second holding component and the first foldable plate, so as to enable the portable electronic device to stand on the second inner surface with a support provided by the input device and the first foldable plate, and the first holding component is capable of being folded relative to the second holding component and the first foldable plate, so as to enable the input device and the second inner surface to cover a display surface of the portable electronic device together.

2. The protective sheath as claimed in claim 1, wherein the first holding component comprises a rear plate and a first holding portion, the rear plate has the first inner surface, and the first holding portion comprises a silicon case, a leather case, a plastic case, at least an elastic, at least a fastening strap or at least an adhesive unit disposed on the first inner surface, or at least a hook disposed on a part of a peripheral of the rear plate, or a combination thereof.

3. The protective sheath as claimed in claim 1, wherein the first holding component is a silicon case, a leather case or a plastic case.

4. The protective sheath as claimed in claim 1, wherein the first holding component further has a third side edge adjacent to the second holding component, a fourth side edge opposite to the third side edge, a fifth side edge connecting with the third side edge and the fourth side edge, a sixth side edge opposite to the fifth side edge and a center region located among the third side edge, the fourth side edge, the fifth side edge and the sixth side edge, and the first foldable plate is pivoted to at least part of the third side edge, at least part of the fourth side edge or the center region, or extends from the fifth side edge to the sixth side edge.

5. The protective sheath as claimed in claim 1, wherein the second holding component comprises a cover plate and a second holding portion, the cover plate has the second inner surface, and the second holding portion comprises at least an elastic, at least a fastening strap, at least an insertion portion or at least an adhesive unit disposed on the second inner surface, or at least a hook disposed on a part of a peripheral of the cover plate, or a combination thereof.

6. The protective sheath as claimed in claim 1, wherein the support component further comprises a third holding portion, and the third holding portion comprises at least an elastic or at least a fastening strap disposed on a third inner surface of the first foldable plate, or a plurality of hooks disposed on a part of a peripheral of the first foldable plate, or a combination thereof.

7. The protective sheath as claimed in claim 1, wherein the second holding component further has an opening and a receiving space connecting with the opening, the second foldable plate is glidingly disposed to the opening, and the second side edge is glidingly disposed within the receiving space.

8. The protective sheath as claimed in claim 7, wherein the support component further has a position limiting portion disposed to the second side edge, a first length of the second foldable plate is shorter than a second length of the opening, a third length of the position limiting portion is longer than the second length and shorter than a fourth length of the receiving space, a fifth length of the position limiting portion is shorter than a sixth length of the receiving space, all of the first length, the second length, the third length and the fourth length are substantially parallel to the second side edge, and both of the fifth length and the sixth length are substantially perpendicular to the second side edge.

9. The protective sheath as claimed in claim 7, wherein the opening is formed at a seventh side edge of the second holding component adjacent to the first holding component.

10. The protective sheath as claimed in claim 1, wherein at least one of the second holding component and the second foldable plate further has at least a slide rail, and the second foldable plate is glidingly disposed to the second holding component via the slide rail.

11. The protective sheath as claimed in claim 10, wherein the slide rail further has at least a position limiting portion capable of limiting a relative position between the second holding component and the second foldable plate.

12. The protective sheath as claimed in claim 1, further comprising a hinge, wherein the first side edge is pivoted to a first outer surface of the first holding component opposite to the first inner surface via the hinge.

13. The protective sheath as claimed in claim 12, wherein the hinge is an embedded hinge.

14. The protective sheath as claimed in claim 12, wherein the hinge is an exposed hinge.

15. The protective sheath as claimed in claim 1, further comprising a third holding component, wherein the third holding component is disposed to at least one of the first holding component and the second holding component, and capable of maintaining the first holding component and the second holding component being folded relative to each other.

16. The protective sheath as claimed in claim 15, wherein the third holding component is at least an elastic disposed to at least one of the first holding component and the second holding component.

17. The protective sheath as claimed in claim 15, wherein the third holding component is a zipper set, at least a fastening strap, at least a snap button set, at least a pair of permanent magnets with opposite magnet polarities, a combination of at least a permanent magnet and at least a ferromagnetic material artifact, a combination of at least a hook and at least a locking aperture, a combination of at least a pin and at least an inserting aperture, or a combination listed above, and is disposed to both of the first holding component and the second holding component.

18. The protective sheath as claimed in claim 17, wherein the first holding component further has a third foldable plate, the third foldable plate is capable of being folded toward a second outer surface of the second holding component opposite to the second inner surface when the first holding component and the second holding component are folded relative to each other, and the third holding component is disposed to both of the third foldable plate and the second outer surface.

19. The protective sheath as claimed in claim 17, wherein the second holding component further has a fourth foldable plate, the fourth foldable plate is capable of being folded toward a first outer surface of the first holding component opposite to the first inner surface when the first holding component and the second holding component are folded relative to each other, and the third holding component is disposed to both of the fourth foldable plate and the first outer surface.

20. The protective sheath as claimed in claim 1, wherein the portable electronic device is a multimedia player, a cell phone, a personal digital assistant, a hand-held game console, a tablet personal computer or an electronic book.

21. The protective sheath as claimed in claim 1, wherein the input device is a keyboard or a graphics tablet.
